(19) United States
(12) Patent Application Publication
(10) Pub. No.: US 2016/0043141 A1
(43) Pub. Date: Feb. 11, 2016

(54) MEMORY DEVICE AND METHOD FOR MANUFACTURING THE SAME

(71) Applicant: Kabushiki Kaisha Toshiba, Minato-ku (JP)

(72) Inventors: Kiyohito NISHIHARA, Yokkaichi (JP); Kikuko SUGIMAE, Kuwana (JP)

(73) Assignee: Kabushiki Kaisha Toshiba, Minato-ku (JP)

(21) Appl. No.: 14/640,521

(22) Filed: Mar. 6, 2015

Related U.S. Application Data
(60) Provisional application No. 62/035,116, filed on Aug. 8, 2014.

(51) Int. Cl. H01L 27/24; H01L 23/528; H01L 23/522; H01L 45/00

(52) U.S. Cl. CPC H01L 27/2463; H01L 45/122; H01L 45/16; H01L 23/528; H01L 23/5226

(57) ABSTRACT

A memory device according to one embodiment includes a substrate, a first wiring placed on the substrate and extending in a first direction, a second wiring placed on the first wiring and extending in a second direction, a memory element coupled the first wiring and the second wiring, an engagement member coupled a portion of the second wiring, the portion is displaced from a region directly above the first wiring, a via engaged with the engagement member, a stopper member placed in a region including a region directly below the engagement member, and an interlayer insulating film provided on the substrate and covering the first wiring, the second wiring, the memory element, the engagement member, the via, and the stopper member.

### CROSS-REFERENCE TO RELATED APPLICATIONS

This application is based upon and claims the benefit of priority from U.S. Provisional Patent Application 62/035,116, filed on Aug. 8, 2014; the entire contents of which are incorporated herein by reference.

### FIELD

Embodiments described herein relate generally to a memory device and a method for manufacturing the same.

### BACKGROUND

Recently, a resistance change film has been developed. In the resistance change film, the electrical resistance is changed by application of current or voltage. A memory element based on such a resistance change film has been proposed. Furthermore, a cross-point structure has been proposed as a structure for integrating such memory elements at high density. The cross-point structure includes a plurality of lower wirings extending in a first direction and a plurality of upper wirings extending in a second direction. A memory element is connected between the lower wiring and the upper wiring. Thus, the memory elements are arranged in a matrix. The lower wirings and the upper wirings are extracted to the outside of the region in which the memory elements are arranged. Thus, the lower wirings and the upper wirings are connected to e.g. peripheral circuits.

### BRIEF DESCRIPTION OF THE DRAWINGS

FIG. 1A is a plan view illustrating a memory device according to an embodiment, FIG. 1B is a sectional view taken along line A-A′ shown in FIG. 1A; and

FIGS. 2A to 4B are process sectional views illustrating a method for manufacturing a memory device according to the embodiment.

### DETAILED DESCRIPTION

According to one embodiment, a memory device includes a substrate, a first wiring placed on the substrate and extending in a first direction being parallel to an upper surface of the substrate, a second wiring placed on the first wiring and extending in a second direction being parallel to the upper surface of the substrate and crossing the first direction, and a memory element coupled the first wiring and the second wiring. The memory device also includes an engagement member coupled a portion of the second wiring, the portion is displaced from a region directly above the first wiring. The memory device also includes a via engaged with the engagement member, a stopper member placed in a region including a region directly below the engagement member, and an interlayer insulating film provided on the substrate and covering the first wiring, the second wiring, the memory element, the engagement member, the via, and the stopper member.

According to one embodiment, a method is disclosed for manufacturing a memory device. The method can include forming a first interlayer insulating film and a first wiring on a substrate, the first wiring is exposed at an upper surface of the first interlayer insulating film and extends in a first direction being parallel to an upper surface of the substrate. The method can also include forming a memory element material film on the first interlayer insulating film, forming a memory element coupled the first wiring and a stopper member spaced from the first wiring by selectively removing the memory element material film, forming a second interlayer insulating film so as to cover the memory element and the stopper member, and performing planarization processing on an upper surface of the second interlayer insulating film using the memory element and the stopper member as a stopper. The method can also include forming a second wiring and an engagement member on the second interlayer insulating film, the second wiring extends in a second direction being parallel to the upper surface of the substrate and crossing the first direction, the second wiring is coupled the memory element, and the engagement member is placed in a region including a region directly above the stopper member and coupled the second wiring. The method can also include forming a third interlayer insulating film so as to cover the second wiring and the engagement member, forming a via hole by selectively removing the third interlayer insulating film so that the engagement member is interposed in the via hole, and forming a via by embedding a conductive material in the via hole.

Embodiments of the invention will now be described with reference to the drawings.

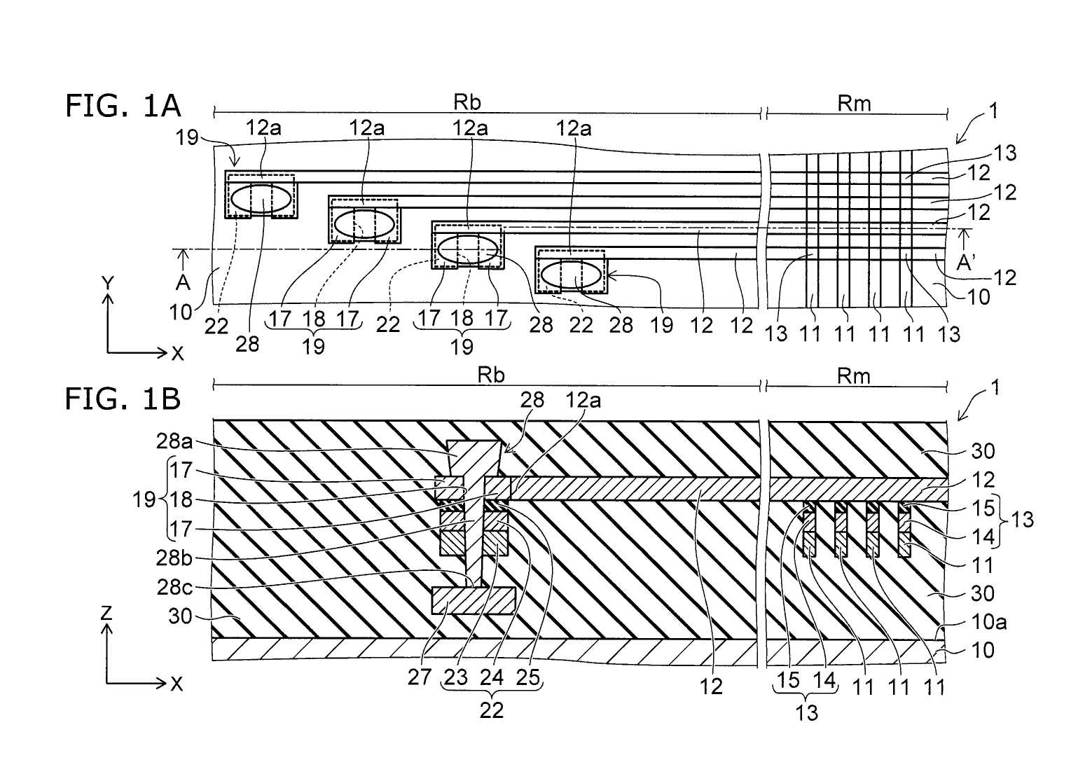

FIG. 1A is a plan view illustrating a memory device according to an embodiment. FIG. 1B is a sectional view taken along line A-A′ shown in FIG. 1A.

As shown in FIGS. 1A and 1B, the memory device 1 according to the embodiment includes a silicon substrate 10.

For convenience of description, an XYZ orthogonal coordinate system is adopted in this specification. Two directions parallel to the upper surface 10a of the silicon substrate 10 and orthogonal to each other are referred to as “X-direction” and “Y-direction”. The direction perpendicular to the upper surface 10a is referred to as “Z-direction”.

A plurality of word lines 11 extending in the Y-direction are provided on the silicon substrate 10. The plurality of word lines 11 are equally spaced on the same XY-plane. A plurality of bit lines 12 extending in the X-direction are provided on the word lines 11. The plurality of bit lines 12 are equally spaced on the same XY-plane. The word line 11 and the bit line 12 are not in contact with each other. The word line 11 and the bit line 12 are formed from a conductive material, e.g., a metal material such as tungsten.

One memory element 13 is connected between each word line 11 and each bit line 12. Thus, as viewed in the Z-direction, the memory elements 13 are arranged in a matrix at respective cross-points of the word lines 11 and the bit lines 12. Each memory element 13 is shaped like a column, such as a quadrangular column, extending in the Z-direction. The region in which the memory element 13 is placed, i.e., the region in which the word line 11 and the bit line 12 cross each other, is referred to as memory cell region Rm.

Each memory element 13 includes an element selection film 14. A resistance change film 15 is provided thereon. The element selection film 14 is a film for controlling whether to pass a current in the memory element 13. The element selection film 14 is e.g. a silicon diode. The resistance change film 15 is made of e.g. metal oxide. Upon application of voltage, a filament is formed inside the resistance change film 15. This decreases the electrical resistance. Upon another application of voltage, the filament is broken. This increases the electrical resistance. The memory element 13 can store e.g. binary data corresponding to the levels of the electrical resistance of the resistance change film 15.

The bit line 12 is extracted from the memory cell region

Rm to one X-direction. A pair of plates 17 spaced from each other in the X-direction extend out from an end part 12a of each bit line 12 to one Y-direction. The plate 17 is formed from a conductive member, e.g., the same material as the bit line 12. The pair of plates 17 and the gap 18 therebetween constitute an engagement member 19. More generally, the engagement member refers to metal members and a region sandwiched between these metal members. The engagement member 19 is provided for each bit line 12 and connected to the end part 12a of the bit line 12. The region in which the engagement member 19 is placed is referred to as bit line extraction region Rb. The bit line extraction region Rb is a region displaced from the memory cell region Rm to one X-direction side.

A stopper member 22 is provided directly below the engagement member 19. Each stopper member 22 is placed only in the region directly below the corresponding engagement member 19. The stopper member 22 is shaped like e.g. a rectangular solid.

Here, the stopper member 22 may protrude from the region directly below the engagement member 19. However, even in this case, the stopper member 22 is not placed directly below the bit lines 12 other than the bit line 12 connected to the engagement member 19 located directly above the stopper member 22. Furthermore, the stopper member 22 is not placed directly below the other engagement members 19 connected to the other bit lines 12. That is, the stopper member 22 is not placed across the regions directly below two or more bit lines 12. The stopper member 22 is not placed across the regions directly below two or more engagement members 19.

In the stopper member 22, from bottom to top, a conductive film 23, a silicon film 24, and a metal oxide film 25 are stacked in this order. The conductive film 23 is formed from the same material as the word line 11. The film thickness of the conductive film 23 is generally equal to the film thickness of the word line 11. The silicon film 24 is formed from the same material as the element selection film 14. The film thickness of the silicon film 24 is generally equal to the film thickness of the element selection film 14. The metal oxide film 25 is formed from the same material as the resistance change film 15. The film thickness of the metal oxide film 25 is generally equal to the film thickness of the resistance change film 15. That is, the film configuration of the stopper member 22 is identical to the film configuration of the word line 11 and the memory element 13. The metal oxide film 25 is in contact with the bit line 12.

A lower wiring 27 is provided in a region on the silicon substrate 10 including the region directly below the engagement member 19. The lower wiring 27 is connected to the silicon substrate 10 and a peripheral circuit (not shown) formed thereabove. Here, the lower wiring 27 is not shown in FIG. 1A.

A via 28 extending in the Z-direction is provided from above the engagement member 19 to the upper surface of the lower wiring 27. The upper end of the via 28 is located above the engagement member 19. The upper part 28a of the via 28 located above the engagement member 19 has a shape in which the longitudinal direction is directed in the arranging direction of the pair of plates 17, i.e., the X-direction, as viewed from above, i.e., the Z-direction. For instance, the upper part 28a is shaped like an ellipse in which the long diameter direction is directed in the X-direction.

The Z-direction intermediate part 28b of the via 28 is engaged with the engagement member 19. More specifically, both X-direction end parts of the via 28 are in contact with the upper surface of the pair of plates 17, and located only above the plates 17. On the other hand, the X-direction center part of the via 28 passes through the gap 18 between the pair of plates 17. The intermediate part 28b of the via 28 penetrates through the stopper member 22 in the Z-direction. The lower end 28c of the via 28 abuts on the upper surface of the lower wiring 27, and is connected to the lower wiring 27.

An interlayer insulating film 30 made of e.g. silicon oxide is provided on the silicon substrate 10. The aforementioned members, i.e., the word line 11, the bit line 12, the memory element 13, the engagement member 19, the stopper member 22, the lower wiring 27, and the via 28 are embedded in the interlayer insulating film 30. Here, the interlayer insulating film 30 is not shown in FIG. 1A.

Next, a method for manufacturing a memory device according to the embodiment is described.

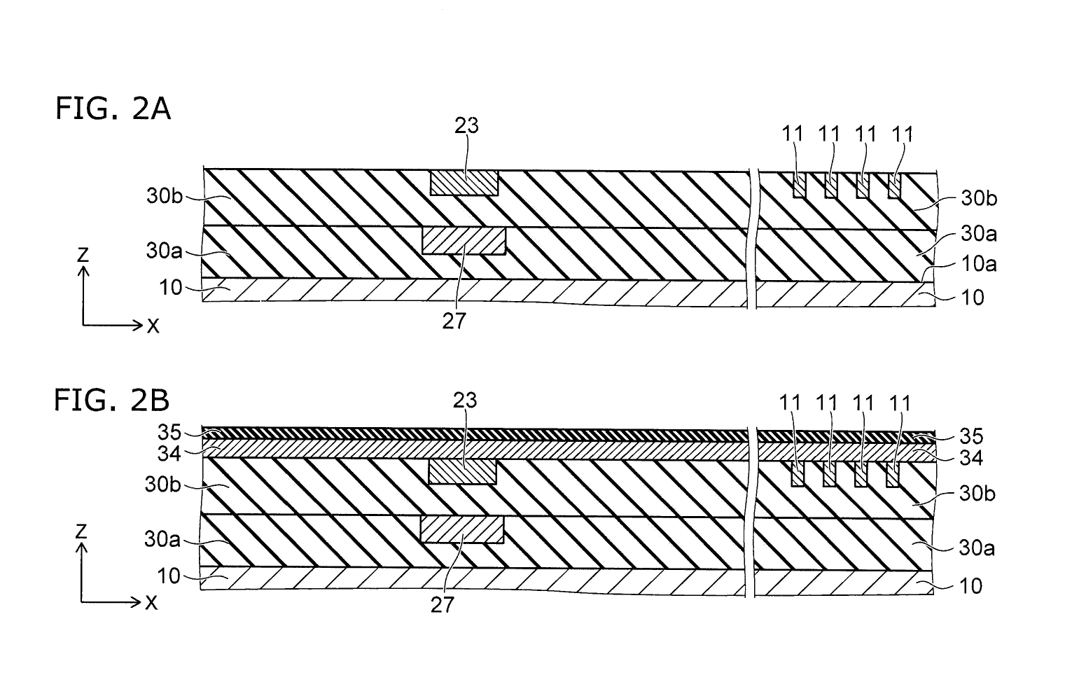

FIGS. 2A to 4B are process sectional views illustrating a method for manufacturing a memory device according to the embodiment.

First, a peripheral circuit (not shown) is formed above the silicon substrate 10 shown in FIG. 2A. A diffusion layer (not shown) is formed in the upper surface 10a of the silicon substrate 10. Next, an interlayer insulating film 30a is formed by depositing e.g. silicon oxide on the silicon substrate 10. Furthermore, a lower wiring 27 is formed. Next, an interlayer insulating film 30b is formed on the interlayer insulating film 30a. Furthermore, a word line 11 and a conductive film 23 are collectively formed in the upper portion of the interlayer insulating film 30b. Here, the conductive film 23 is formed in part of the region directly above the lower wiring 27, and spaced from the word line 11.

Specifically, the word line 11 and the conductive film 23 may be formed by e.g. the damascene method. In this case, a trench is formed in the upper portion of the interlayer insulating film 30b. Subsequently, a conductive material is deposited to form a conductive film. Then, the portion of the conductive material formed on the upper surface of the interlayer insulating film 30b is removed by planarization processing such as CMP (chemical mechanical polishing). Thus, a word line 11 and a conductive film 23 are formed in the trench.

Alternatively, the word line 11 and the conductive film 23 may be formed by e.g. the RIE (reactive ion etching) method. In this case, one conductive film is formed on the interlayer insulating film, and then selectively removed by RIE. Thus, the conductive film is processed into a word line 11 and a conductive film 23. Subsequently, an insulating material is deposited so as to embed the word line 11 and the conductive film 23. Thus, an interlayer insulating film 30b is formed. The upper surface of the interlayer insulating film 30b is subjected to planarization processing such as CMP.

Next, as shown in FIG. 2B, a silicon film 34 is formed on the entire surface. A metal oxide film 35 is formed on the silicon film 34. The metal oxide film 35 is a resistance change film. The silicon film 34 and the metal oxide film 35 constitute a memory element material film.

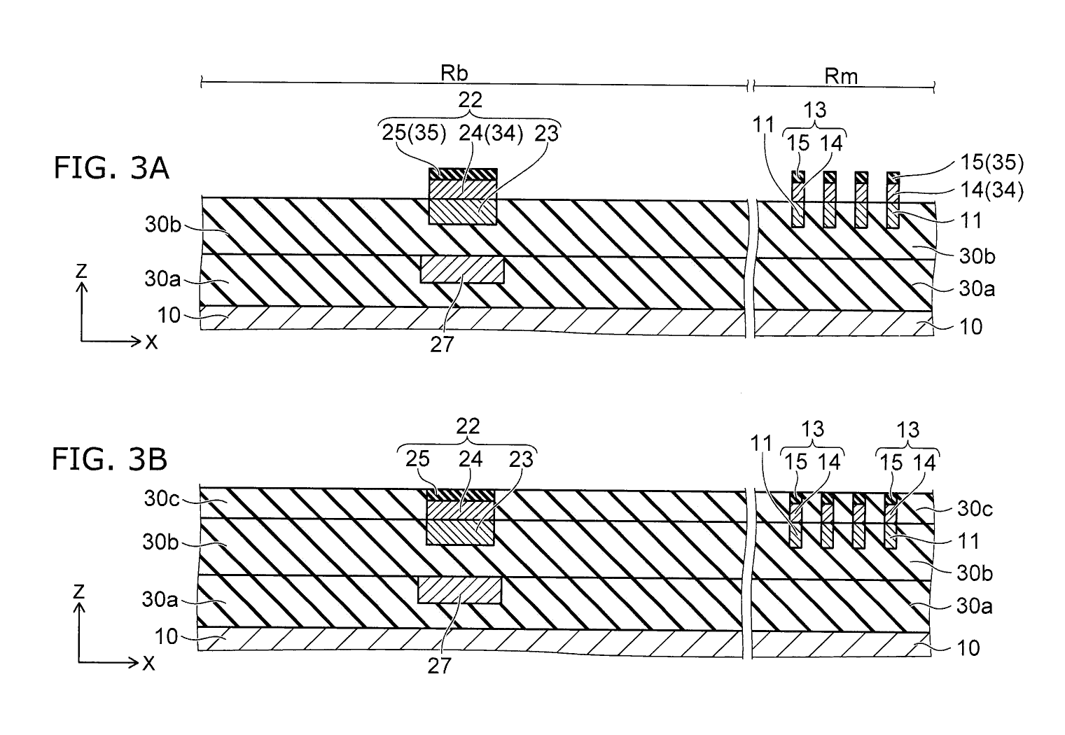

Next, as shown in FIG. 3A, the metal oxide film 35 and the silicon film 34 are selectively removed by anisotropic etching such as RIE. Thus, in the memory cell region Rm, the metal oxide film 35 and the silicon film 34 left in part of the region directly above the word line 11 constitute an element selection film 14. In the bit line extraction region Rb, the metal oxide film 35 and the silicon film 34 left in the region directly above the conductive film 23 constitute a metal oxide film 25 and a silicon film 24. The element selection film 14 and the resistance change film 15 form a memory element 13. The conductive film 23, the silicon film 24, and the metal oxide film 25 form a stopper member 22. The stopper member 22 is spaced from the word line 11.

Next, as shown in FIG. 3B, an interlayer insulating film 30c is formed on the interlayer insulating film 30b. The upper surface of the interlayer insulating film 30c is subjected to planarization processing such as CMP. Thus, the upper surface of the resistance change film 15 and the upper surface of the metal oxide film 25 are exposed at the upper surface of the interlayer insulating film 30c.

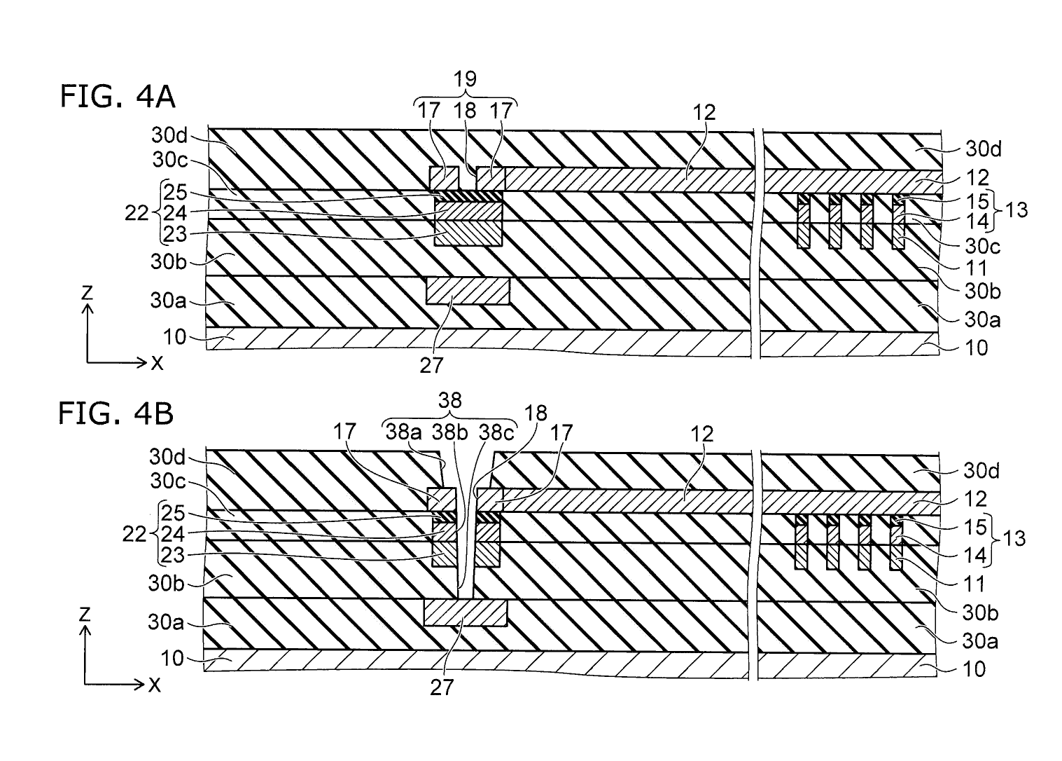

Next, as shown in FIG. 4A, a conductive film is formed on the interlayer insulating film 30c and patterned. Thus, a bit line 12 and a pair of plates 17 are integrally formed. A gap 18 is formed between the plates 17. Next, an interlayer insulating film 30d is formed on the interlayer insulating film 30c so as to cover the bit line 12 and the plates 17.

Next, as shown in FIG. 4B, a resist pattern (not shown) is formed on the interlayer insulating film 30d by e.g. the lithography method. An opening shaped like e.g. an ellipse is formed in the resist pattern. The long diameter direction of the ellipse is directed in the X-direction. Next, the resist pattern is used as a mask to perform anisotropic etching such as RIE under the condition of selectively etching the interlayer insulating film 30d.

Thus, the interlayer insulating film 30d is selectively removed. Accordingly, a via hole 38a is formed in the interlayer insulating film 30d. When the via hole 38a reaches the plate 17 and the gap 18, the plate 17 is exposed at the bottom surface of the via hole 38a. The plate 17 is scarcely etched. Thus, the portion of the via hole 38a reaching the plate 17 does not extend downward any further. On the other hand, the portion of the via hole 38a reaching the gap 18 extends downward in the gap 18. Thus, a pair of plates 17 are interposed in the via hole 38. A step difference is formed at the upper surface of the plate 17 on the side surface of the via hole 38.

After the via hole 38a reaches the stopper member 22, anisotropic etching is performed under the condition of selectively etching the metal oxide film 25 to penetrate through the metal oxide film 25. Next, anisotropic etching is performed under the condition of selectively etching the silicon film 24 to penetrate through the silicon film 24. Next, anisotropic etching is performed under the condition of selectively etching the conductive film 23 to penetrate through the conductive film 23. Thus, a via hole 38b is formed in the stopper member 22. As viewed in the Z-direction, the via hole 38b is formed inside the overlapping region of the gap 18 and the via hole 38a.

Next, anisotropic etching is performed under the condition of selectively etching the interlayer insulating film 30b. Thus, a via hole 38c is formed in the region directly below the via hole 38b in the interlayer insulating film 30b. After the via hole 38c reaches the lower wiring 27, the anisotropic etching is stopped. The via holes 38a, 38b, and 38c communicate with each other to form one via hole 38.

Next, as shown in FIGS. 1A and 1B, a conductive material such as a metal material of e.g. tungsten, copper, or aluminum is embedded in the via hole 38. Thus, a via 28 is formed in the via hole 38. Next, an interlayer insulating film 30 is formed on the interlayer insulating film 30d. In FIG. 1B and the description thereof, the interlayer insulating films 30a, 30b, 30c, 30d, and 30 are collectively referred to as interlayer insulating film 30. Thus, the memory device 1 according to the embodiment is manufactured.

Next, the effect of the embodiment is described.

In the embodiment, in the step shown in FIG. 2A, the conductive film 23 is formed simultaneously with the word line 11. Thus, the conductive film 23 serves as a stopper for CMP when the upper surface of the interlayer insulating film 30b is subjected to CMP. This can suppress what is called dishing in the bit line extraction region Rb. Dishing is the phenomenon in which the upper surface of the interlayer insulating film 30b is significantly depressed.

In the embodiment, in the step shown in FIGS. 2B and 3A, the silicon film 24 is formed simultaneously with the element selection film 14. The metal oxide film 25 is formed simultaneously with the resistance change film 15. Thus, the stopper member 22 composed of the conductive film 23, the silicon film 24, and the metal oxide film 25 is formed. Accordingly, in the step shown in FIG. 3B, the stopper member 22 serves as a stopper for CMP when the upper surface of the interlayer insulating film 30c is subjected to CMP. This can suppress dishing in the bit line extraction region Rb.

Thus, the embodiment can suppress dishing in each CMP step. Accordingly, the occurrence of manufacturing failure due to dishing can be suppressed in the steps after the CMP step. As a result, the yield of the memory device 1 can be improved.

In the embodiment, in the step shown in FIG. 2A, the conductive film 23 is formed simultaneously with the word line 11. In the step shown in FIGS. 2B and 3A, the silicon film 24 is formed simultaneously with the element selection film 14. The metal oxide film 25 is formed simultaneously with the resistance change film 15. Thus, there is no need to add a dedicated step for forming the stopper member 22. This can suppress the increase of manufacturing cost of the memory device 1.

Furthermore, in the embodiment, each stopper member 22 is not placed across the regions directly below two or more bit lines 12. Furthermore, each stopper member 22 is not placed across the regions directly below two or more engagement members 19. This can prevent the leakage current from flowing through the stopper member 22 between two or more bit lines 12 or between two or more engagement members 19. Due to e.g. processing failure, the metal oxide film 25 may be made electrically continuous in the film thickness direction. Then, the bit line 12 in contact with the upper surface of this metal oxide film 25 is short-circuited to the conductive film 23 in contact with the lower surface of the metal oxide film 25. However, even in this case, no short circuit occurs between two bit lines 12.

In particular, in the embodiment, each stopper member 22 is formed inside the region directly below the corresponding engagement member 19. This can reliably prevent the occurrence of leakage current through the stopper member 22. Here, the width of the engagement member 19 is wider than the width of the bit line 12. Thus, the area of the stopper member 22 can be made larger. Thus, the stopper member 22 can reliably function as a stopper for CMP. In an example, for a sufficient function as a stopper, the length of the stopper member 22 in the X-direction and the Y-direction is preferably set to several hundred nanometers or more. Thus, miniaturization of the arrangement pitch of the bit lines 12 would make it difficult to place the stopper member 22 only in the region directly below the bit line 12 without lying across the regions directly below a plurality of bit lines 12.

The embodiment has been described with reference to an example in which the memory element 13 includes an element selection film 14 made of a silicon diode and a resistance change film 15 made of metal oxide. However, the embodiment is not limited thereto. For instance, the element selection film 14 does not need to be provided. The resistance change film 15 is not limited to a metal oxide film. For instance, the resistance change film 15 may be made of amorphous silicon. An ion supply film containing e.g. silver may be provided on the resistance change film 15. In this case, a positive voltage is applied with the ion supply film serving as a positive electrode and the resistance change film 15 serving as a negative electrode. Thus, silver contained in the ion supply film is ionized and migrates in the resistance change film 15. Thus, a filament is formed in the resistance change film 15 to decrease the electrical resistance of the resistance change film 15. Furthermore, by application of a reverse voltage, silver forming the filament in the resistance change film 15 is ionized and migrates toward the ion supply film. This breaks the filament and increases the electrical resistance of the resistance change film 15. In the embodiment, the stopper member 22 is not placed across the regions directly below two or more bit lines 12. Thus, it is also possible to provide a conductive film in the uppermost layer of the stopper member 22.

The embodiment has been described with reference to an example in which the bit line extraction region Rb is provided only on one X-direction side of the memory cell region Rm. However, the bit line extraction region Rb may be provided on both X-direction sides of the memory cell region Rm. In this case, adjacent bit lines 12 may be extracted alternately in the opposite directions and connected to the engagement members 19.

Furthermore, the embodiment has been described with reference to an example provided with one word line wiring layer including a plurality of word lines 11 and one bit line wiring layer including a plurality of bit lines 12. However, the word line wiring layer and the bit line wiring layer may be alternately stacked. Thus, the memory elements 13 can be arranged in three dimensions. In this case, a stopper member 22 having the same film configuration as the wirings and the memory elements 13 in the next lower layer can be provided directly below each layer of word lines 11 and bit lines 12 except the lowermost word lines 11.

The embodiments described above can realize a memory device and a method for manufacturing the same with high reliability.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A memory device comprising:
a substrate;
a first wiring placed on the substrate and extending in a first direction being parallel to an upper surface of the substrate;
a second wiring placed on the first wiring and extending in a second direction being parallel to the upper surface of the substrate and crossing the first direction;
a memory element coupled the first wiring and the second wiring;
an engagement member coupled a portion of the second wiring, the portion being displaced from a region directly above the first wiring;
a via engaged with the engagement member;
a stopper member placed in a region including a region directly below the engagement member; and
an interlayer insulating film provided on the substrate and covering the first wiring, the second wiring, the memory element, the engagement member, the via, and the stopper member.

2. The device according to claim 1, wherein the stopper member is placed only in the region directly below the engagement member.

3. The device according to claim 1, wherein composition of at least a part of the stopper member is identical to composition of at least a part of the first wiring and the memory element.

4. The device according to claim 1, wherein composition of a lower part of the stopper member is identical to composition of the first wiring, and composition of an upper part of the stopper member is identical to composition of the memory element.

5. The device according to claim 1, wherein film configuration of the stopper member is identical to film configuration of the first wirings and the memory element.

6. The device according to claim 1, wherein the via penetrates through the stopper member.

7. The device according to claim 1, further comprising:
another second wiring placed on the first wiring and extending in the second direction;
another engagement member coupled the another second wiring; and
another stopper member placed in the region directly below the another engagement member.

8. The device according to claim 7, wherein
a position of the engagement member and a position of the another engagement member are different each other in the second direction.

9. The device according to claim 1, wherein
the engagement member includes a pair of plates extending out from the second wiring and spaced from each other, and
the via is in contact with upper surfaces of the pair of plates and passes between the pair of plates.

10. The device according to claim 9, wherein a portion of the via located above the engagement member has a shape with longitudinal direction directed in the arranging direction of the pair of plates as viewed from above.

11. The device according to claim 1, wherein the memory element includes a resistance change film.

12. The device according to claim 1, further comprising:
a lower wiring coupled a lower end of the via.

13. A memory device comprising:
a substrate;
a plurality of first wirings placed on the substrate and extending in a first direction being parallel to an upper surface of the substrate;
a plurality of second wirings placed on the first wirings and extending in a second direction being parallel to the upper surface of the substrate and crossing the first direction;
a plurality of memory elements coupled the first wirings and the second wirings;
a plurality of engagement members coupled portions of the second wirings, the portions being displaced from regions directly above the first wirings and displaced from regions directly above a region between the first wirings;
a plurality of vias engaged with the engagement members respectively;
a plurality of stopper members placed in regions, each of the regions including a region directly below each of the engagement members; and
an interlayer insulating film provided on the substrate and covering the first wirings, the second wirings, the memory elements, the engagement members, the vias, and the stopper members.

14. The device according to claim 13, wherein
positions of the engagement members are different one another in the second direction.

15. A method for manufacturing a memory device, comprising:
forming a first interlayer insulating film and a first wiring on a substrate, the first wiring being exposed at an upper surface of the first interlayer insulating film and extending in a first direction being parallel to an upper surface of the substrate;
forming a memory element material film on the first interlayer insulating film;
forming a memory element coupled the first wiring and a stopper member spaced from the first wiring by selectively removing the memory element material film;
forming a second interlayer insulating film so as to cover the memory element and the stopper member;
performing planarization processing on an upper surface of the second interlayer insulating film using the memory element and the stopper member as a stopper;
forming a second wiring and an engagement member on the second interlayer insulating film, the second wiring extending in a second direction being parallel to the upper surface of the substrate and crossing the first direction, the second wiring being coupled the memory element, and the engagement member being placed in a region including a region directly above the stopper member and coupled the second wiring;
forming a third interlayer insulating film so as to cover the second wiring and the engagement member;
forming a via hole by selectively removing the third interlayer insulating film so that the engagement member is interposed in the via hole; and
forming a via by embedding a conductive material in the via hole.

16. The method according to claim 15, wherein
a conductive film spaced from the first wiring is formed in the forming the first wiring, and
the forming the first wiring includes performing planarization processing on an upper surface of the first interlayer insulating film using the first wiring and the conductive film as a stopper.

17. The method according to claim 15, wherein the stopper member is penetrated through the via hole in the forming the via hole.

18. The method according to claim 15, wherein the forming the memory element material film includes forming a resistance change film.

19. The method according to claim 15, further comprising:
forming a lower wiring on the substrate,
wherein the stopper member is formed in part of a region directly above the lower wiring in the forming the stopper member, and
the via hole is caused to reach the lower wiring in the forming the via hole.
